(19) United States
(12) Patent Application Publication
(10) Pub. No.: US 2015/0354050 A1
(43) Pub. Date: Dec. 10, 2015

(54) DEPOSITION WELDING WITH EXTERNAL THICK FRAME CONTOURS

(71) Applicant: SIEMENS AKTIENGESELLSCHAFT, München (DE)

(72) Inventor: Bernd BURBAUM, Falkensee (DE)

(21) Appl. No.: 14/761,243

(22) PCT Filed: Jan. 14, 2014
(86) PCT No.: PCT/EP2014/050584

§ 371 Date: Jul. 15, 2015

(30) Foreign Application Priority Data
Jan. 21, 2013 (EP) 13151995.1

(51) Int. Cl. C23C 4/12; C23C 16/44

(52) U.S. Cl. CPC C23C 4/127; C23C 16/44

(57) ABSTRACT

The susceptibility of cracking in the region of the edges (16) is prevented in a modified application process in the region of the edge, which surrounds a surface (13) which is to be welded, due to the use of a wider track of material or a different material for the external contour welding (2).

### CROSS-REFERENCE TO RELATED APPLICATIONS

The present application is a 35 U.S.C. §§371 national phase conversion of PCT/EP2014/050584, filed Jan. 14, 2014, which claims priority of European Application No. 13151995.1, filed Jan. 21, 2013, the contents of which are incorporated by reference herein. The PCT International Application was published in the German language.

### TECHNICAL FIELD

The invention relates to deposition welding on a surface.

### TECHNICAL BACKGROUND

Deposition welding methods, in particular laser deposition welding methods, are known from the prior art and are used in particular also in the context of turbine blades in order to build up the blade tip with its contour over an entire surface or in the shape of walls of the blades.

The rim region still represents a critical point, in both the context of the deposition welding and the tendency to cracks, since it is a transition from the material to the air.

It is therefore an object of the present invention to solve the problem mentioned above.

### BRIEF DESCRIPTION OF THE DRAWINGS

FIG. 1 shows a substrate in cross section,

FIG. 2 shows a view of a welded face,

FIG. 3 shows a turbine blade.

### DESCRIPTION OF EMBODIMENTS

The figures and the description represent only exemplary embodiments of the invention.

FIG. 1 shows a cross section through a substrate 7, in which a deposition weld is already partially present.

In particular, the region of the edge 19 of the substrate 7, in this case preferably a blade tip, represents a critical region.

For that reason, an outer contour weld 2 is first laid or applied.

The outer contour weld 2 preferably is comprised of a different first welding material 16 than are the plurality of the inner welding tracks 10 which are comprised of a second welding material 11.

The outer contact weld is broader than the inner welding tracks 10. Preferably, the breadth of the outer contact weld is at least 50% greater than the breadth of each of the inner welding tracks 10. The outer contact weld preferably has only one welding track.

Being of a different material means that at least one alloy fraction of a first welding material 16 differs by at least 20% from that of the second welding material 11.

Along the edge 19 of a face of a substrate to be welded, a material is used for the outer contact weld which is less prone to hot cracking.

Inside this outer contour weld 2, a deposition weld is then created in the face 13 therebetween, using a different welding material 11 which is closer to the mechanical properties of the substrate 7 than the material of the contour weld 2 and is more prone to cracking.

Alternatively, the outer contour weld 2 can be generated using the same material as the material 11, but the contour weld is substantially broader overall than the inner welding tracks 10.

Preferably, the outer contour weld 2 also projects over the corner or edge 19.

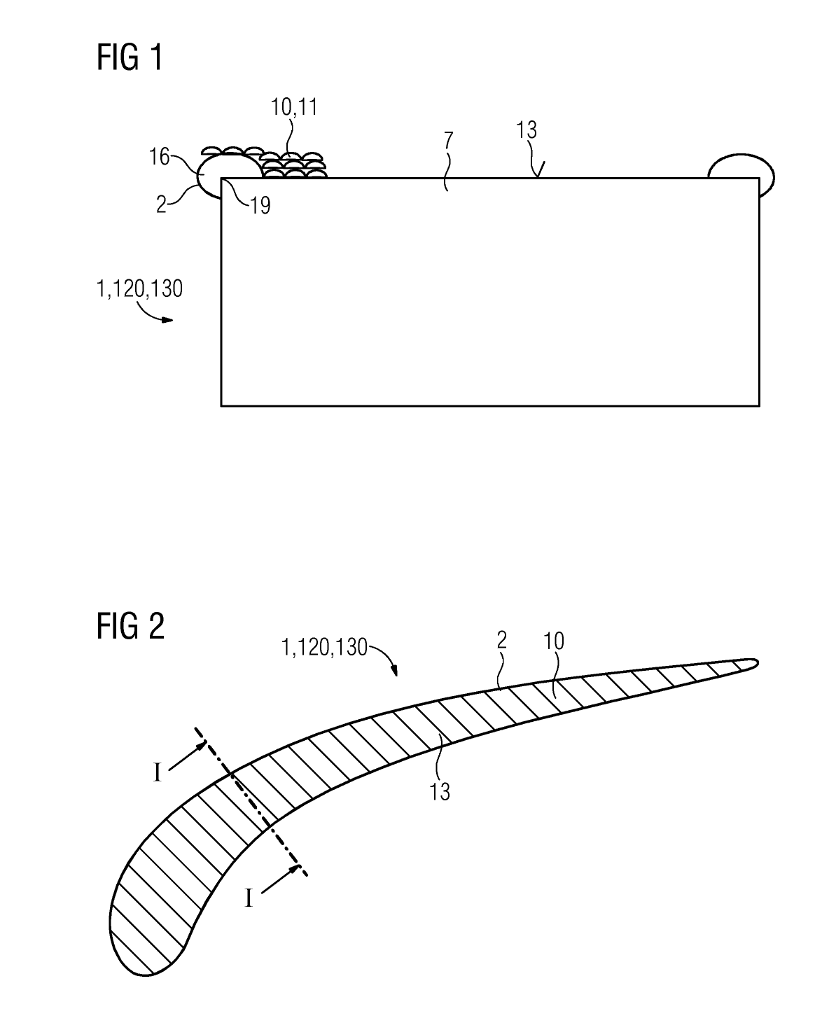

FIG. 2 shows a view of such a weld, in which the thick line represents the outer contour weld 2 which is laid all around the periphery of the face 13 to be welded, that is the weld 2 runs all along an edge 19 and here encloses a blade airfoil profile. In that context, multiple welding tracks 10, made in any desired shape, are present in addition to the first material.

Equally, different welding materials can be used for the outer contour weld 2 and the inner welding tracks 10, and a broader outer contour weld 2.

The outer contour weld 2 represents a single welding track or welding bead.

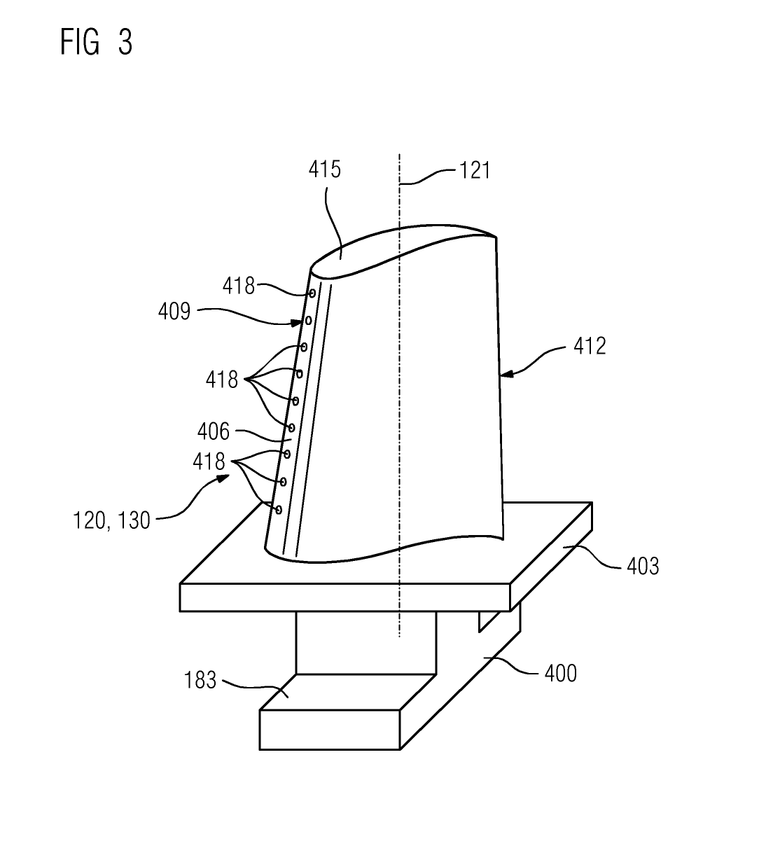

FIG. 3 shows a perspective view of a movable blade 120 or stationary blade 130 of a turbomachine, which extends along a longitudinal axis 121.

The turbomachine may be a gas turbine of an aircraft or of a power plant for generating electricity, a steam turbine or a compressor.

The blade 120, 130 has, in succession along the longitudinal axis 121, a securing region 400, an adjoining blade platform 403 and a blade airfoil 406 and a blade tip 415.

As a stationary blade 130, the blade 130 may have a further platform (not shown) at its blade tip 415.

A blade root 183, which is used to secure the movable blades 120, 130 to a shaft or a disk (not shown), is formed in the securing region 400.

The blade root 183 is designed, for example, in hammerhead form. Other configurations, such as a fir-tree or dovetail root, are possible.

The blade 120, 130 has a leading edge 409 and a trailing edge 412 for a medium which flows past the blade airfoil 406.

In the case of conventional blades or vanes 120, 130, by way of example solid metallic materials, in particular superalloys, are used in all regions 400, 403, 406 of the blade or vane 120, 130.

Superalloys of this type are known, for example, from EP 1 204 776 B1, EP 1 306 454, EP 1 319 729 A1, WO 99/67435 or WO 00/44949.

The blade 120, 130 may in this case be produced by a casting process, by means of directional solidification, by a forging process, by a milling process or combinations thereof.

Workpieces with a single-crystal structure or structures are used as components for machines which, in operation, are exposed to high mechanical, thermal and/or chemical stresses.

Single-crystal workpieces of this type are produced, for example, by directional solidification from the melt. This involves casting processes in which the liquid metallic alloy solidifies to form the single-crystal structure, i.e. the single-crystal workpiece, or solidifies directionally. In this case, dendritic crystals are oriented along the direction of heat flow and form either a columnar crystalline grain structure (i.e. grains which run over the entire length of the workpiece and are referred to here, in accordance with the language customarily used, as directionally solidified) or a single-crystal structure, i.e. the entire workpiece consists of one single crystal. In these processes, a transition to globular (polycrystalline) solidification needs to be avoided, since non-directional growth inevitably forms transverse and longitudinal grain boundaries, which negate the favorable properties of the directionally solidified or single-crystal component.

Where the text refers in general terms to directionally solidified microstructures, this is to be understood as meaning both single crystals, which do not have any grain boundaries or at most have small-angle grain boundaries, and columnar crystal structures, which do have grain boundaries running in the longitudinal direction but do not have any transverse grain boundaries. This second form of crystalline structures is also described as directionally solidified structures.

Processes of this type are known from U.S. Pat. No. 6,024,792 and EP 0 892 090 A1.

The blades or vanes 120, 130 may likewise have coatings protecting against corrosion or oxidation e.g. (MCrAlX; M is at least one element selected from the group consisting of iron (Fe), cobalt (Co), nickel (Ni), X is an active element and stands for yttrium (Y) and/or silicon and/or at least one rare earth element, or hafnium (Hf)). Alloys of this type are known from EP 0 486 489 B1, EP 0 786 017 B1, EP 0 412 397 B1 or EP 1 306 454 A1.

The density is preferably 95% of the theoretical density.

A protective aluminum oxide layer (TGO=thermally grown oxide layer) is formed on the MCrAlX layer (as an intermediate layer or as the outermost layer).

The layer preferably has a composition Co-30Ni-28Cr-8Al-0.6Y-0.75i or Co-28Ni-24Cr-10Al-0.6Y. In addition to these cobalt-based protective coatings, it is also preferable to use nickel-based protective layers, such as Ni-10Cr-12Al-0.6Y-3Re or Ni-12Co-21Cr-11Al-0.4Y-2Re or Ni-25Co-17Cr-10Al-0.4Y-1.5Re.

It is also possible for a thermal barrier coating, which is preferably the outermost layer and consists for example of ZrO₂, Y₂O₃—ZrO₂, i.e. it is unstabilized, partially stabilized or fully stabilized by yttrium oxide and/or calcium oxide and/or magnesium oxide, to be present on the MCrAlX.

The thermal barrier coating covers the entire MCrAlX layer. Columnar grains are produced in the thermal barrier coating by suitable coating processes, such as for example electron beam physical vapor deposition (EB-PVD).

Other coating processes are possible, e.g. atmospheric plasma spraying (APS), LPPS, VPS or CVD. The thermal barrier coating may include grains that are porous or have micro-cracks or macro-cracks, in order to improve the resistance to thermal shocks. The thermal barrier coating is therefore preferably more porous than the MCrAlX layer.

Refurbishment means that, after they have been used, protective layers may have to be removed from components 120, 130 (e.g. by sand-blasting). Then, the corrosion and/or oxidation layers and products are removed. If appropriate, cracks in the component 120, 130 are also repaired. This is followed by recoating of the component 120, 130, after which the component 120, 130 can be reused.

The blade 120, 130 may be hollow or solid in form. If the blade 120, 130 is to be cooled, it is hollow and may also have film-cooling holes 418 (indicated by dashed lines).

1. A method for deposition welding of a face of a component, comprising,
applying an outer contour weld around the face of the component, wherein the outer contour weld is comprised of a first welding material,
depositing a second welding material on the face of the component at a location inward on the face of the component from the outer contour weld, the first welding material is less prone to cracks than the second welding material.

2. The method as claimed in claim 8, wherein the first welding material for the outer contour weld is comprised of a different welding material than the second welding material of the inner welding tracks on the face to be welded.

3. The method as claimed in 8, wherein the breadth of the outer contour weld is at least 50% greater, than the breadth of each of the inner welding tracks.

4. The method as claimed in claim 8, wherein the outer contour weld ust has only one welding track.

5. The method as claimed in claims 1, further comprising applying the outer contour weld is laid over an edge of the face.

6. A component,
produced by the method as claimed in claim 1,
for deposition welding of a face of a component, comprising,
an outer contour weld around the face, wherein the outer contour weld is comprised of a first welding material, and
a second welding material deposited on the face of the component at a location inward on the face of the component from the outer contour weld, the first welding material is less prone to cracks than its second welding material.

7. The component as claimed in claim 6, wherein the outer contour weld projects over an edge of the face.

8. The method as claimed in claim 1,
further comprising applying the second welding material to the face of the component at a location inward on the face of the component from the outer contour weld in the form of a plurality of inner welding tracks over the face.

9. The method as claimed in claim 8, wherein the outer contour weld is applied at least 50% broader than each welding track of the inner welding tracks.

10. The method as claimed in claim 8, wherein the outer contour weld has only one welding track.

11. The method as claimed in claim 8, further comprising applying the outer contour weld over an edge of the face.

12. The component of claim 8, wherein the first welding material for the outer contour weld comprises a different welding material than the second welding material of the inner welding tracks on the face to be welded.

13. The component of claim 10, wherein the breadth of the outer contour weld is at least 50% greater than the breadth of each of the inner welding tracks.

14. The component of claim 6, wherein the outer contour weld has only one welding track.
